(19) United States
(12) Patent Application Publication
(10) Pub. No.: US 2026/0271406 A1
(43) Pub. Date: Sep. 10, 2026

(54) SEMICONDUCTOR DEVICE WITH LOW LEAKAGE ANTENNA DIODE

(71) Applicant: Taiwan Semiconductor Manufacturing Company, Ltd., Hsinchu (TW)

(72) Inventors: Yi-Yang Chao, Hsinchu (TW); Hsing-Kan Peng, Hsinchu (TW); Pin-Dai Sue, Hsinchu (TW); Che-Wei Chang, Hsinchu (TW); Chia-En Huang, Hsinchu (TW); Ting-Wei Chiang, Hsinchu (TW)

(21) Appl. No.: 19/071,537

(22) Filed: Mar. 5, 2025

(51) Int. Cl. H10D 89/60; H10D 84/01

(52) U.S. Cl. CPC H10D 89/611; H10D 84/0109; H10D 89/921

(57) ABSTRACT

A semiconductor device with a low leakage antenna diode is provided. The semiconductor device includes a semiconductor substrate and a n-well and a p-well formed in or on the substrate. A first circuit element is formed in or on the n-well. An antenna diode formed in or on the p-well. A punch through mitigation structure is formed between the first circuit element and the antenna diode. The punch through mitigation structure is configured to mitigate a punch through current between the first circuit element and the antenna diode.

### BACKGROUND

The semiconductor integrated circuit (IC) industry has experienced rapid growth. The ongoing trend in miniaturizing ICs has resulted in progressively smaller devices that consume less power, yet provide more functionality at higher speeds than earlier technologies. Such miniaturization has been achieved through design and manufacturing innovations tied to increasingly strict specifications. Various electronic design automation tools are used to generate, revise, and verify and designs for semiconductor devices while ensuring that IC structure design and manufacturing specifications are met.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A-1J are diagrams illustrating a semiconductor device with cut metal gate structures in accordance with some embodiments.

FIGS. 2A-2L are diagrams illustrating a semiconductor device with fully bulk isolation structures in accordance with some embodiments.

FIGS. 3A-3F are diagrams illustrating a semiconductor device with P+ epi source/drain structures in accordance with some embodiments.

FIGS. 4A-4F are diagrams illustrating a semiconductor device with P+ epi source/drain structures and grounded gate structures in accordance with some embodiments.

FIG. 5 is a flow diagram illustrating a method for forming a semiconductor device, in accordance with some embodiments.

FIG. 6 is a block diagram of a layout diagram generation system, in accordance with some embodiments.

FIG. 7 is a block diagram of a manufacturing system and a manufacturing flow associated therewith, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

An Integrated Circuit (IC) layout is generated after numerous steps of an IC design, also called a “data preparation stage,” and a series of checks in a process, called “physical verification,” at the end. Examples of common checks in this verification process are Design Rule Checking (DRC), Layout Versus Schematic (LVS), parasitic extraction, antenna rule checking which will be discussed in detail below, and Electrical Rule Checking (ERC). When all verification is complete, the data in the IC layout is translated into an industry standard format, typically a vector-based format, such as GDSII or OASIS, and sent to a semiconductor foundry, called a fab house. The foundry then converts, via Mask Data Preparation (MDP) procedure, the data into a set of instructions by which a photomask writer can generate a physical mask (a photomask) to be used in a photolithographic process of semiconductor device fabrication. More recent MDP procedures require the additional steps associated with design for manufacturability such as, Resolution Enhancement Technologies (RET) and Optical Proximity Correction (OPC). By using a series of photomasks, in addition to other processes, a wafer having one or more die (chips) is fabricated.

Thus, during fabrication, the semiconductor devices are typically subjected to numerous processes using plasma, for example, plasma etching or Reactive Ion Etch (RIE), thin film deposition, ashing, and/or other processes including plasma. For example, interconnections may be formed by etching patterns (e.g., lines) in blanket conductive layers. The energies used to perform such processing may cause integrated circuit layers including the interconnect lines, gate electrodes, to become electrically charged. These conductive lines then act as an antenna, collecting charge. As the conductive lines may be connected to a gate of a device. The charge build-up can cause damage to the gate dielectric (e.g., gate oxide) of the device. In particular, the charge excesses may degrade the device performance, for example, trapped charges can lower the breakdown voltage of the gate.

The conventional processes provide a diode (also referred to as an antenna diode) which provides a discharge path for electrical charge accumulated on a gate electrode layer (e.g., polysilicon). The conventional antenna diode structure includes a N+node and a p-well (PW). As charge accumulates during the process, the N+node can be elevated to a high voltage, causing a reverse leakage from the N+node to the PW to conduct the positive charge to the ground of the PW. However, if the distance between the n-well (NW) and the antenna diode is too short, punch-through may occur, leading to a high leakage current. To resolve this issue, the disclosure provides punch through mitigation structures and processes to suppress the punch through current between a circuit element formed in or on NW and the antenna diode. The punch through mitigation structures may include cut metal gate (CMG) structures, fully bulk isolation (FBI) structures, P+ epi source/drain structures, grounded gate structures, and a combination thereof.

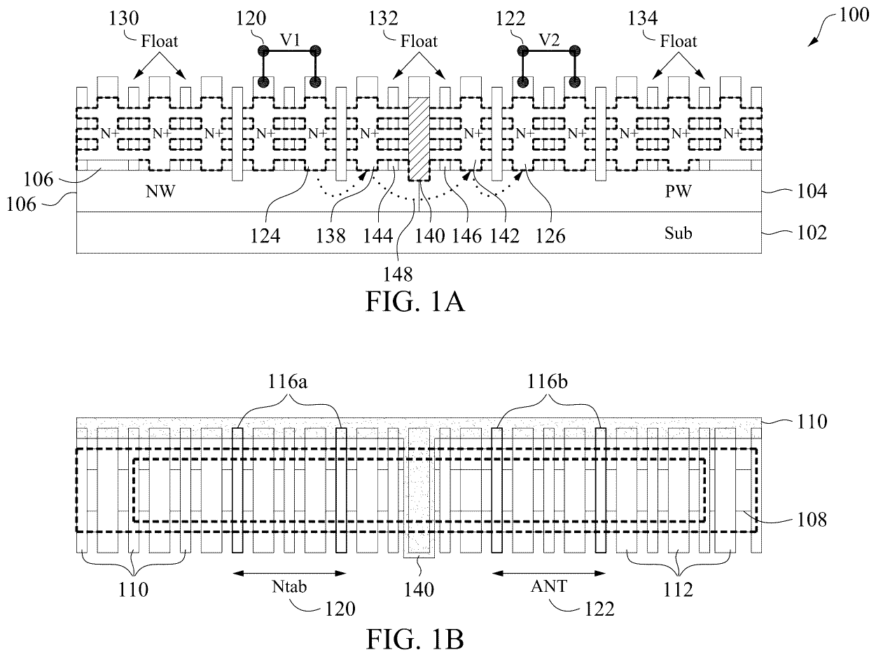

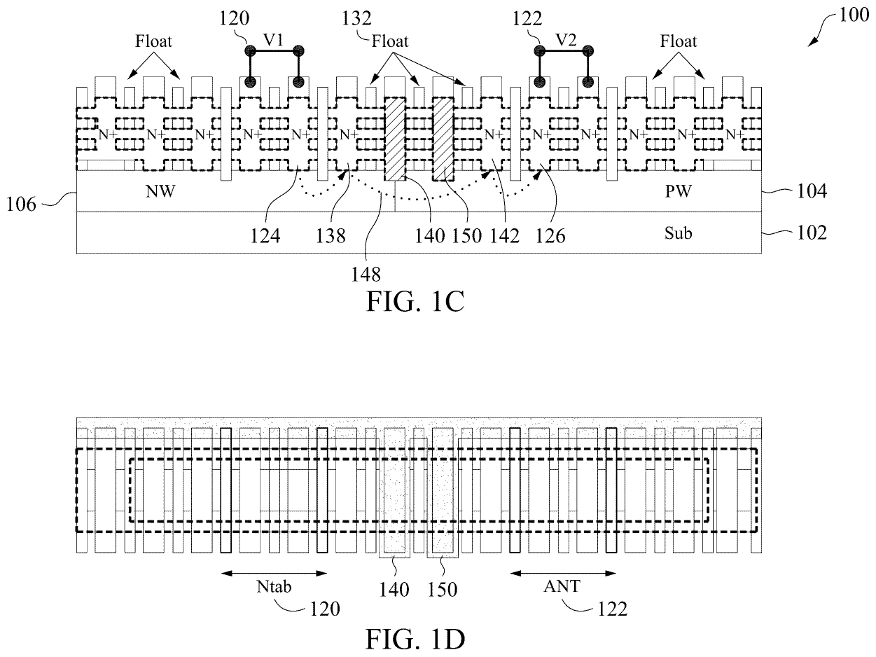

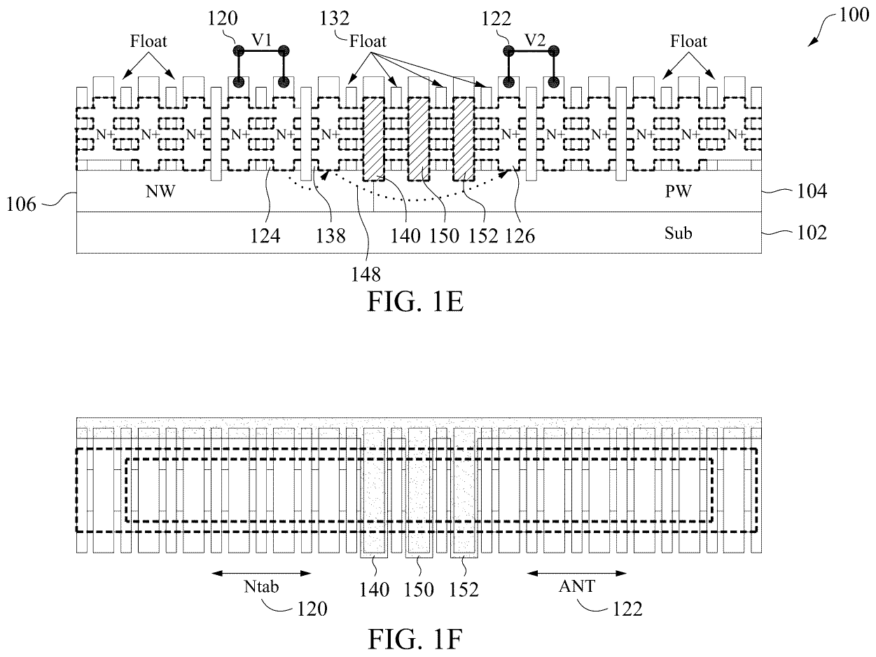

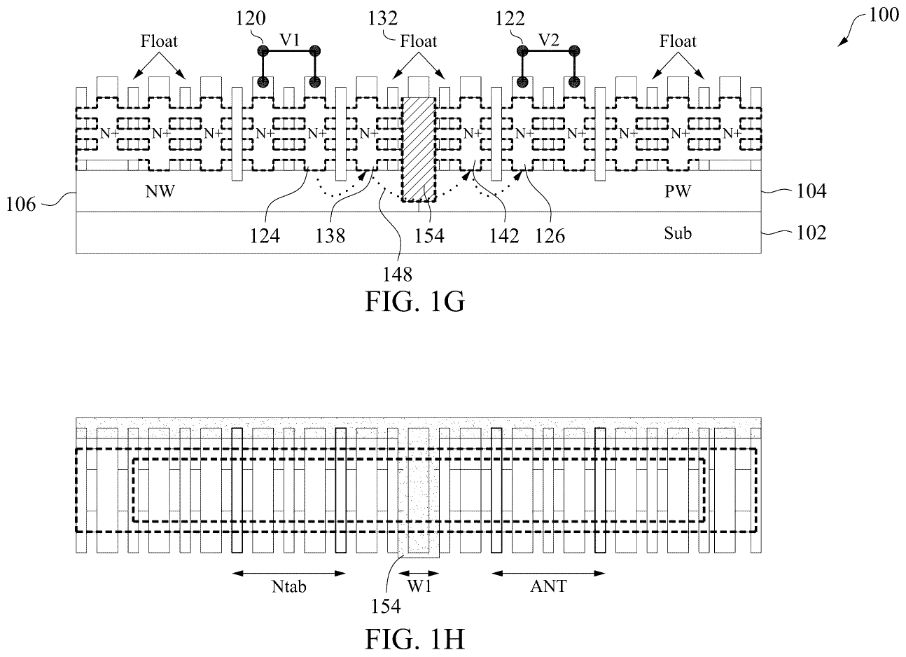

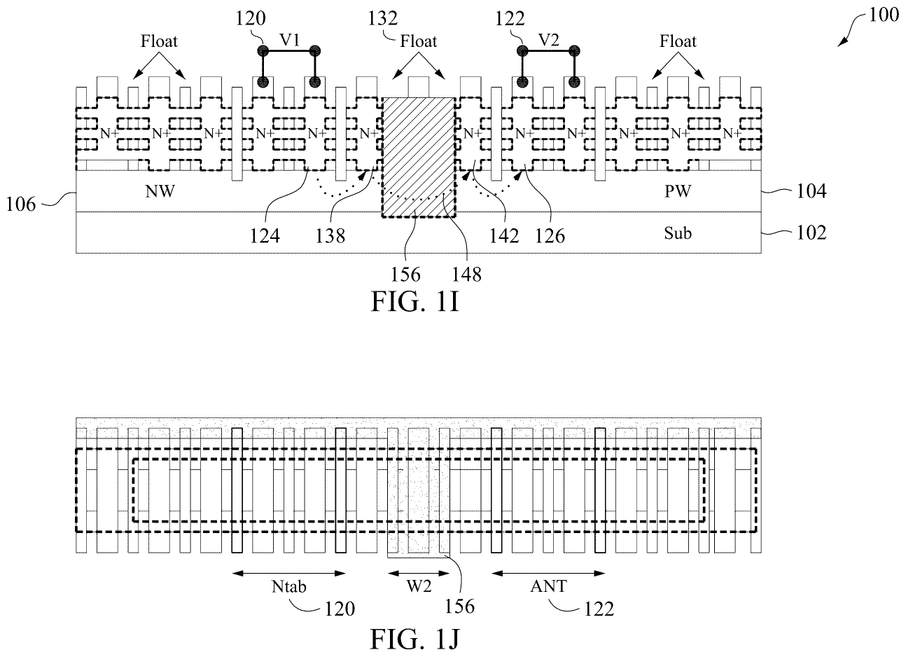

FIGS. 1A-1J are diagrams or layouts illustrating a semiconductor device 100 with CMG structures in accordance with some embodiments. For example, FIGS. 1A and 1B illustrate semiconductor device 100 with a CMG structure. More specifically, FIG. 1A illustrates a sectional view of semiconductor device 100 and FIG. 1B illustrates a top view of semiconductor device 100 with a CMG structure. As shown in FIGS. 1A and 1B, first semiconductor device 100 includes a substrate 102. Substrate 102 is a silicon in crystalline structure, In some examples, substrate 102 may include another elementary semiconductor, such as germanium; a compound semiconductor, such as silicon carbide, silicon phosphide, gallium arsenide, gallium phosphide, indium phosphide, indium arsenide, and/or indium antimonide; an alloy semiconductor, such as SiGe, SiPC, GaAsP, AnnAs, AlGaAs, GalnAs, GaInP, and/or GaInAsP; or combinations thereof. Alternatively, substrate 102 is a semiconductor-on-insulator substrate, such as a silicon-on-insulator (SOI) substrate, a silicon germanium-on-insulator (SGOI) substrate, or a germanium-on-insulator (GOI) substrate. Further, substrate 102 may optionally include an epitaxial layer (epi), may be strained for performance enhancement, and/or have other suitable enhancement features.

In accordance with example implementations, substrate 102 may be P substrate (Psub), that is, a silicon wafer that is doped with p-type impurities, for example, infused with elements such as boron or gallium. These impurities introduce excess holes (positive charge carriers) in the silicon lattice making it a p-type material. Substrate 102 may be used as a base layer onto which various other layers are added to create active regions. For example, and as shown in FIGS. 1A and 1B, substrate 102 includes a P-type doped region (for example, a PW 104) doped with P-type dopants, such as boron (for example, BF2), indium, other P-type dopant, or combinations thereof. In addition, substrate 102 includes a N-type doped region (for example, N-type well (NW) 106) doped with N-type dopants, such as phosphorus, arsenic, other N-type dopant, or combinations thereof. PW 104 and NW 106 are formed directly on or in substrate 102.

An oxide diffusion (OD) layer 108 is formed on PW 104 and NW 106. OD layer 108, also referred to as an active region or active diffusion, defines diffusion of active area of a transistor i.e., the area where the source, drain and channel under the gate of transistor are formed. OD layer 108 includes at least one channel region, at least one source region, and at least one drain region, where a channel region is disposed between a source region and a drain region (generally referred to as source/drain regions). Gate structures 110 are disposed over the channel regions of OD layer 108. Gate structures 110 are arranged substantially parallel to one another. Gate structures 110 engage respective channel regions of OD layer 108 such that current can flow between respective source/drain regions. In examples, gate structures 110 include a metal gate with the gate electrode including a metal composition. Examples of suitable metals for forming the gate electrode may include Cu, W, Ti, Ta, TiN, TaN, NiSi, CoSi, and/or combinations thereof.

First semiconductor device 100 further include source/drain features 112. Source/drain features 112 are arranged substantially parallel to each other and are provided as source/drain regions. Source/drain features 112 may comprise semiconductor materials such as silicon (Si), phosphorus (P), silicon phosphide (SiP), silicon carbide (SiC), germanium (Ge), silicon germanium (SiGe), one or more III-V materials, a compound semiconductor, or an alloy semiconductor. In some examples, source/drain features 112 are doped with N-type dopants. Source/drain features 112 and gate structures 110 may be placed or formed in alternate to each other.

First semiconductor device 100 further include isolation features 116a, 116b. Isolation features 116 (for example, a shallow trench isolation (STI) feature) are formed over and/or in substrate 102 and provides isolation for an active region or for a circuit element. For example, isolation feature 116a provides isolation for a N-well Taps and Biasing (NTAB) 120 from other active and/or passive regions of first semiconductor device 100. NTAB 100 is a biasing structure for NW 106, that is, for connecting NW 106 to a defined voltage V1 (for example, VDD or a positive supply voltage). Biasing NW 106 to the defined voltage may ensure proper functioning of p-channel Metal Oxide Semiconductor (PMOS) transistors that are bult in NW 106. For example, biasing NW 106 to the defined voltage may stabilize the threshold voltage of PMOS transistors. In examples, NTAB 120 is also referred to as a first circuit element.

Isolation feature 116b provides isolation for an antenna diode 122 from other active and/or passive regions of first semiconductor device 100. Isolation features 116a, 116b may include silicon oxide (SiO), silicon nitride (SiN), silicon oxynitride (SiON), other suitable isolation material (for example, including silicon, oxygen, nitrogen, carbon, or other suitable isolation constituent), or combinations thereof. Antenna diode 122 provides a discharge path for electrical charge accumulated on a gate electrode layer (e.g., polysilicon). Antenna diode 122 may be connected to a defined voltage V2 (for example, the ground, or 0V). In some examples, therefore, PW 104 may be biased at 0V. In one example, antenna diode 122 may be three poly pitch (3 PP) away from NTAB 120. First semiconductor device 100 further includes multiple floats 130, 132, 134. Floats 130, 132, 134 may be floating gates that are a type of electrically isolated gate structures within a transistor.

In examples, and as disclosed previously, in conventional approach, a punch through current may develop between NTAB 120 and antenna diode 122, that is, between a source/drain structure 124 of NTAB 120 and a source/drain structure 126 of antenna diode 126 that is closest to source/drain structure 124 of NTAB cell 120. For instance, each source/drain structures located between NTAB 120 and antenna diode 122 may accumulate charge (that is, charge accumulating nodes) thereby causing a punch through current between themselves, and hence between NTAB 120 and antenna diode 122. That is, a punch through current may develop between source/drain structure 124 of NTAB cell 120 and source drain structure 126 of antenna diode 126 through source/drain structure 124 of NTAB cell 120 to a source/drain structure 138, from source/drain structures 138 to a source/drain structures 140, from source/drain structures 140 to a source/drain structures 142, and finally from source/drain structure 140 to source/drain structure 126 of antenna diode 122.

In an example embodiment, the punch through current between NTAB 120 and antenna diode 126 is mitigated by forming a punch through mitigation structure (for example, a CMG structure 140) between at least two charge accumulating nodes between NTAB 120 and antenna 122. CMG structure 140 increases a conductive distance between the two charge accumulating nodes between NTAB 120 and antenna diode 122.

In one example, CMG structure 140 is formed by using a CMG process to remove N+epi from a source/drain structure that is located between gate structure 144 and gate structure 146 of float 132. In examples, the N+ epi from a source/drain structure is removed by using advanced multi-patterning lithography techniques to create a mask to define regions where the source/drain structure should be cut and using etching process to remove the N+ epi from the defined regions. In some examples, insulating material may be provided in the defined regions. Thus, CMG structure may include a source/drain region with dopants or N+ epi replaced with an insulating material.

Removing N+ epi creates CMG structure 140 that may not hold any charge. This inhibits the source/drain structure that is located between gate structure 144 and gate structure 146 from becoming a charge accumulation node, and therefore, a part of a punch through current path. Therefore, the punch through current now must be established between source/drain structures 138 and source/drain structures 142 (two closest charge accumulation nodes). This increases a punch through distance 148 to 2 PP (instead of 1 PP) thereby suppressing or mitigating the punch through current between NTAB 120 and antenna diode 122.

In example implementations, the conductive distance 148 may further be increased by forming additional CMG structures between NTAB 120 and antenna diode 122. For example, FIGS. 1C and 1D illustrate semiconductor device 100 with first additional CMG structure 150 formed between CMG structure 140 and source/drain structure 142. As shown in FIG. 1C, forming first additional CMG 150 further increases punch through distance 148 between source/drain structure 138 and source/drain structure 142 to 3 PP. This increase further increases the overall punch through distance between NTAB 120 and antenna diode 122 thereby further mitigating the punch through current between NTAB 120 and antenna diode 122.

Any number of CMG structures may be formed between NTAB 120 and antenna diode 122 to increase punch through distance 148. For example, FIGS. 1E and 1F illustrate semiconductor device 100 with more than one additional CMG structures (for example, first additional CMG structure 150 and second additional CMG structure 152) are formed between CMG structure 140 and source/drain structure 142. As shown in FIG. 1E, forming first additional CMG 150 and second additional CMG structure 152 further increases punch through distance 148 between source/drain structure 138 and source/drain structure 142 to 4 PP. This further increases the overall punch through distance between NTAB 120 and antenna diode 122 thereby further mitigating the punch through current between NTAB 120 and antenna diode 122. In examples, more than three CMG structures may be formed between NTAB 120 and antenna diode 122 to further suppress the punch through current. However, a higher number of CMG structures may come with an increased area penalty.

In accordance with example embodiments, an etching length, a width, and/or a depth of one or more CMG structures may be varied to further mitigate the punch through current between NTAB 120 and antenna diode 122. FIGS. 1G and 1H illustrate semiconductor device 100 with a CMG structure 154 that is wider (that is, a width of W1) than a width of and deeper/longer than a depth/length of a source/drain structure. In addition, FIGS. 1I and 1J illustrate semiconductor device 100 with a CMG structure 156 that is even wider (that is, a width of W2, where W2 is greater than W1) than and even deeper/longer than CMG structure 154 of FIGS. 1G and 1H. For example, W2 is approximately equal to 1 PP. That is, CMG structure 156 of FIGS. 1I and 1J has a width encompassing float 122. Increased width and increased depth/length further suppresses the punch through current between NTAB cell 120 and antenna diode 122 as the punch through current may needs to be established over an even longer distance. However, increased width and increased depth/length may come with an added area penalty and/or formation process complexity.

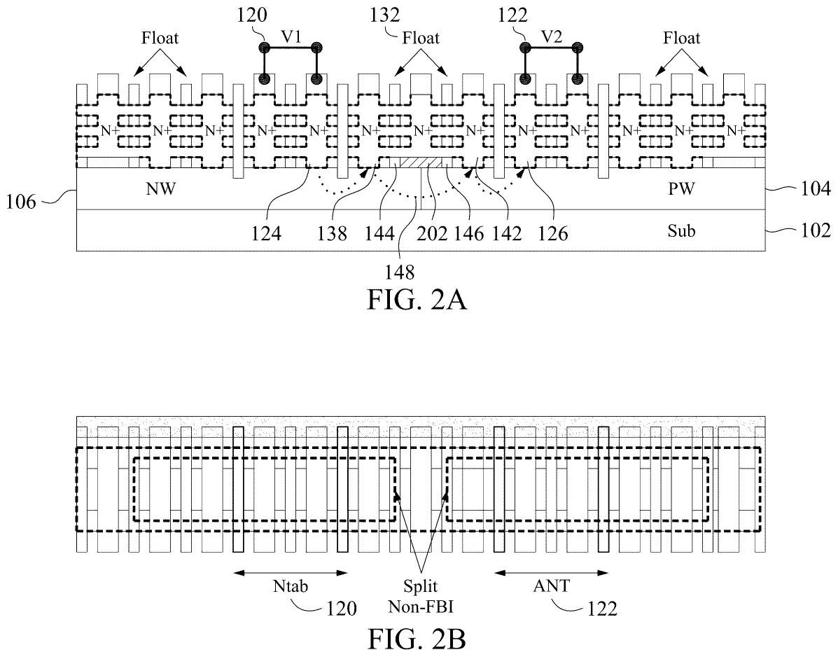

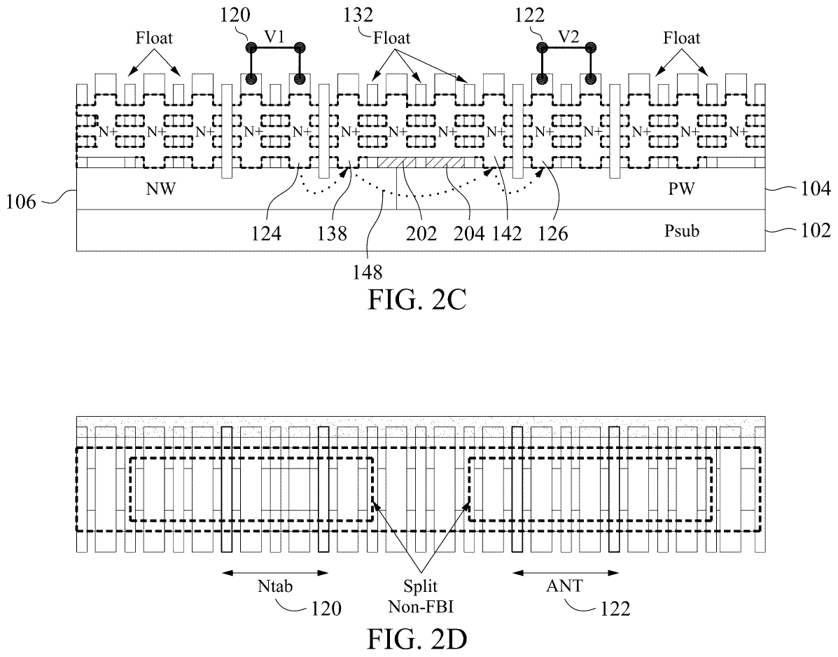

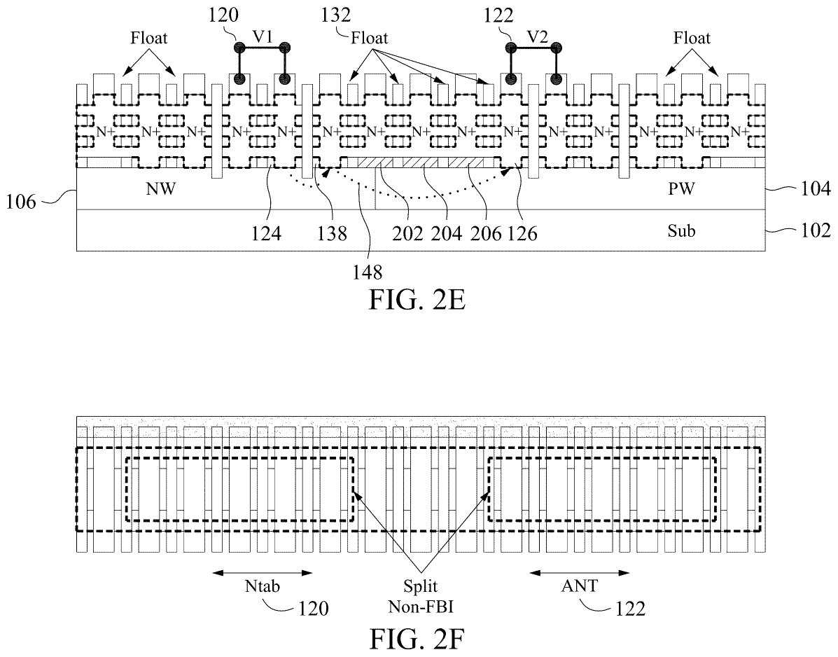

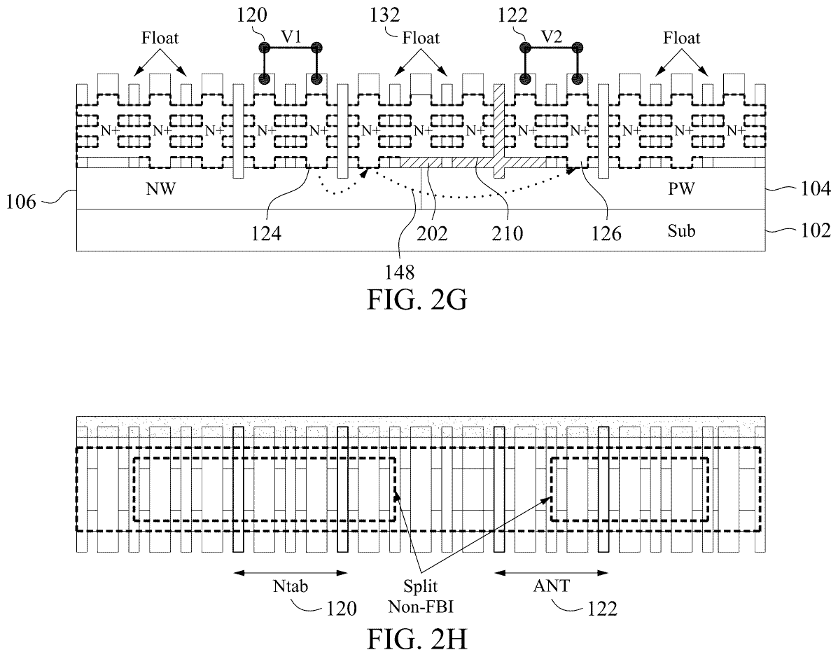

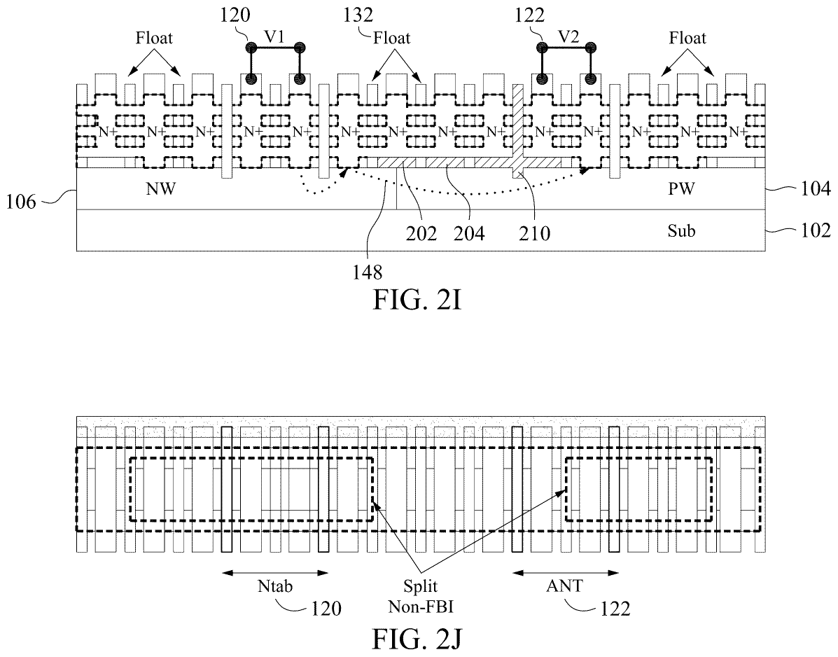

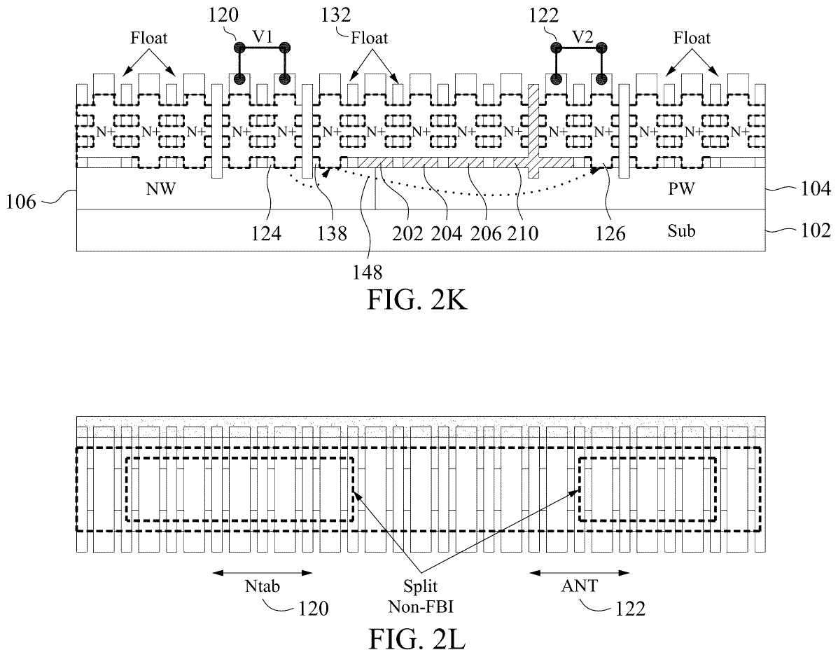

FIGS. 2A-2L are diagrams or layouts illustrating a semiconductor device with FBI structures. For example, FIGS. 2A and 2B illustrate semiconductor device 100 with an FBI structure 202. In accordance with example embodiments, FBI structure 202 is formed using an FBI process to electrically isolate one or more source/drain structures between NTAB 120 and antenna diode 126. As shown in FIGS. 2A and 2B, FBI structure 202 is created under on a source/drain structure that is located between gate structure 144 and gate structure 146 of float 132. Creating FBI structure 202 under a source/drain structure electrically isolates that source/drain structure from the punch through current path. The punch through current now must be established between source/drain structures 138 and source/drain structures 142. This increases punch through distance 148 between source/drain structure 138 and source/drain structure 142 to 2 PP from 1 PP. Increase in punch through distance 148 suppresses or mitigates the punch through current between NTAB 120 and antenna diode 122. Although, in FIGS. 2A and 2B, FBI 202 is formed under the source/drain structure that is located between gate structure 144 and gate structure 146 of float 132, FBI 202 may be formed under any source/drain structures located between NTAB 120 and antenna diode 122.

In accordance with example embodiments, punch through distance 148 may further be increase by forming addition FBI structures between source/drain structure 138 and source/drain structure 142 or between NTAB 120 and antenna diode 122. FIGS. 2C and 2D illustrate semiconductor device 100 with a first additional FBI structure 204 formed between FBI structure 202 and antenna diode 122. As shown in FIG. 2C, creating two FBI structures (that is, FBI structure 202 and first additional FBI structure 204) increases punch through distance 148 to 3 PP. This further increases the overall punch through distance between NTAB 120 and antenna diode 122 thereby further suppressing or mitigating the punch through current between NTAB 120 and antenna diode 122.

Any number of FBI structures may be formed between NTAB 120 and antenna diode 122 to increase the punch through distance 148. For example, FIGS. 2E and 2F illustrate semiconductor device 100 where two additional FBI structures (that is, first additional FBI structure 204 and second additional FBI structure 206) are formed between FBI structure 202 and antenna diode 122. As shown in FIG. 2E, creating two additional FBI structures increases punch through distance 148 to 3 PP. This further increases the overall punch through distance and hence the punch through current between NTAB cell 120 and antenna diode 122. In examples, any number of FBI structures may be formed between NTAB cell 120 and antenna diode 122 to further suppress the punch through current. However, a higher number of FBI structures may come with an increased area penalty.

In accordance with example embodiments, enlarged FBI structures may be formed to further increase punch through distance 148 and further mitigate punch through current between NTAB 120 and antenna diode 122. FIGS. 2G and 2H illustrate semiconductor device 100 with an enlarged FBI structure 210. Enlarged FBI structure 210 is wider than a width of a source/drain structure. For example, a width of FBI 210 is approximately equal to 2 PP thereby extending punch through distance 148 to 3 PP using only two FBI structures. Similarly, FIGS. 2I and 2J illustrate semiconductor device 100 with FBI structure 202, FBI structure 204, and enlarged FBI structure 210. As shown in FIG. 2I, punch through distance 148 is increased to 4 PP using only 3 FBI structures. Furthermore, FIGS. 2K and 2L illustrate semiconductor device 100 with FBI structure 202, FBI structure 204, FBI structure 206, and enlarged FBI structure 210. As illustrated in FIG. 2K, punch through distance 148 is increased to 5 PP using four FBI structures. Thus, an increase in a number of FBI structures and a width of one or more of the FBI structures further increases punch through distance 148, and hence, further increases suppression or mitigation of the punch through current between NTB 120 and antenna diode 122. However, an increased number of FBI structures and/or increased dimensions of FBI structures may come with increased area penalty and formation complexity.

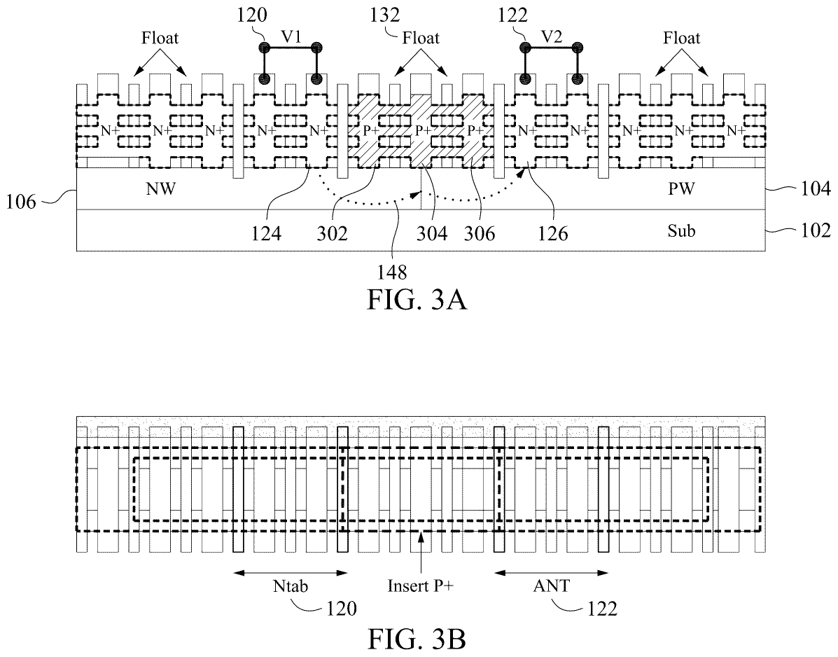

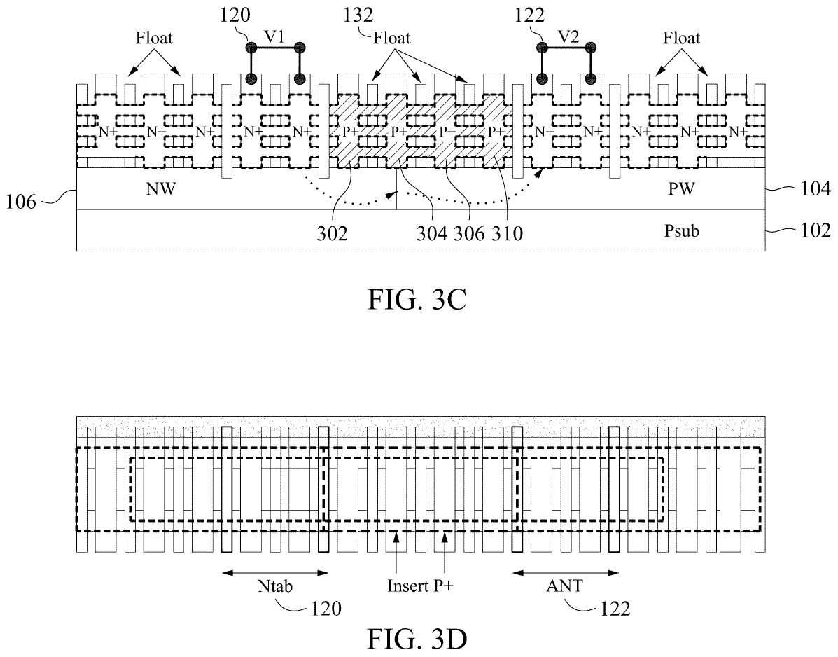

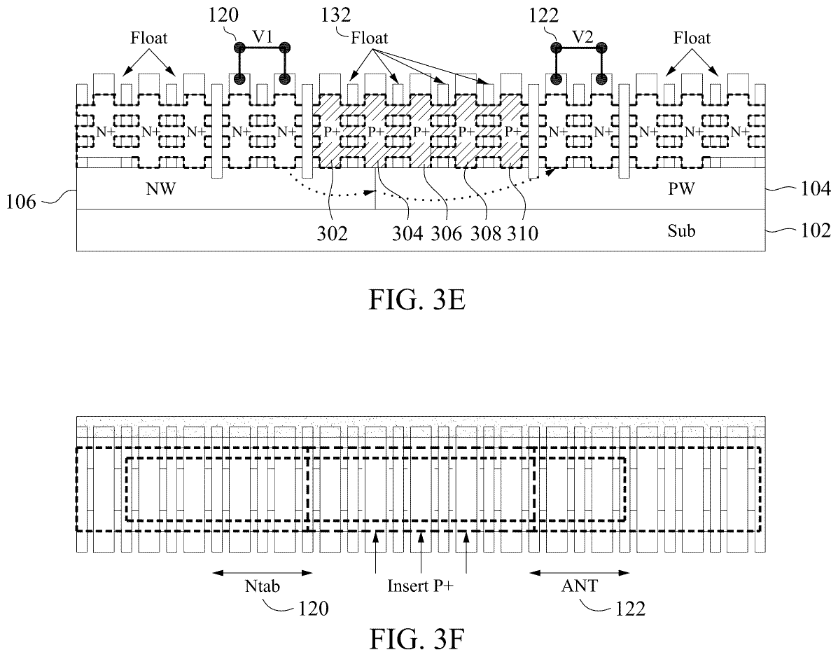

In accordance with example embodiments, the punch through current between NTAB 120 and antenna diode 122 is mitigated or suppressed by forming one or more P+ epi layer structures between them. For example, one or more source/drain structures between NTAB 120 and antenna diode 122 may be heavily doped with acceptor impurities (for example, Boron) that create holes (that is, positive charge carriers) thereby mitigating charge flow between source/drain structures. FIGS. 3A-3F are diagrams or layouts illustrating semiconductor device 100 with P+ epi source/drain structures. For example, as shown in FIGS. 3A and 3B, a first P+ epi source/drain structure 302, a second P+ epi source/drain structure 304, and a third P+ epi source/drain structure 306 may be formed between NTAB 120 and antenna diode 122. Each of first, second and third P+ epi source/drain structures 302, 304, and 306 suppress accumulation of charge and hence a punch through current. This suppresses or mitigates the punch through current between NTAB 120 and antenna diode 122. Although, in FIGS. 3A and 3B, semiconductor device 100 is shown to include three P+ epi source/drain structures, it can include a different number of P+ epi source/drain structures.

For example, FIGS. 3C and 3D illustrate semiconductor device 100 with four P+epi source/drain structures, that is, first P+ epi source/drain structure 302, second P+ epi source/drain structure 304, third P+ epi source/drain structure 306, and fourth P+ epi source/drain structure 308, between NTAB 120 and antenna diode 122. FIGS. 43 and 3F illustrate semiconductor device 100 with five P+ epi layer structures, that is, first P+ epi source/drain structure 302, second P+ epi source/drain structure 304, third P+ epi source/drain structure 306, fourth P+ epi source/drain structure 308, and fifth P+ epi source/drain structure 310, between NTAB 120 and antenna diode 122. Increasing the number of P+ epi source/drain structures may enhance suppression or mitigation of the punch through current between NTAB 120 and antenna diode 122, but it increases area penalty.

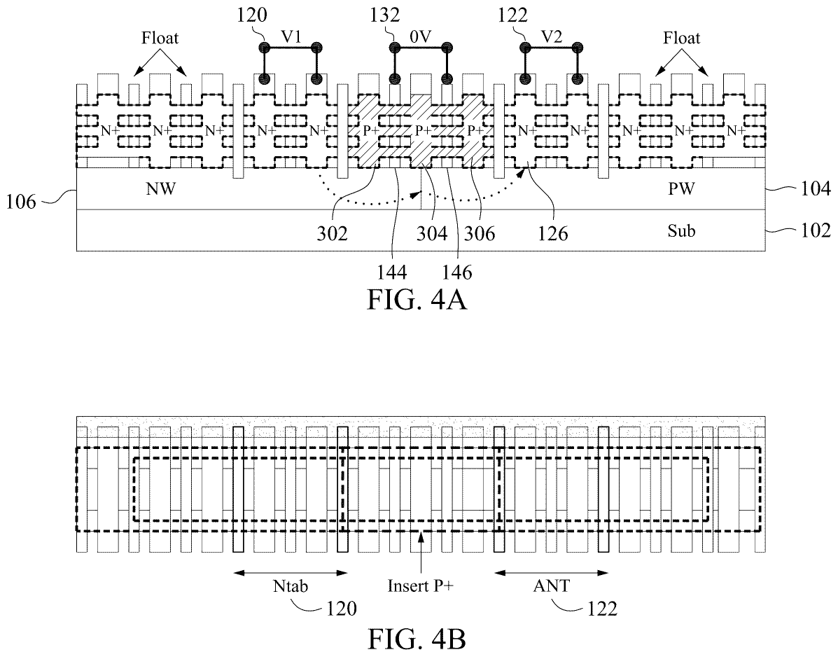

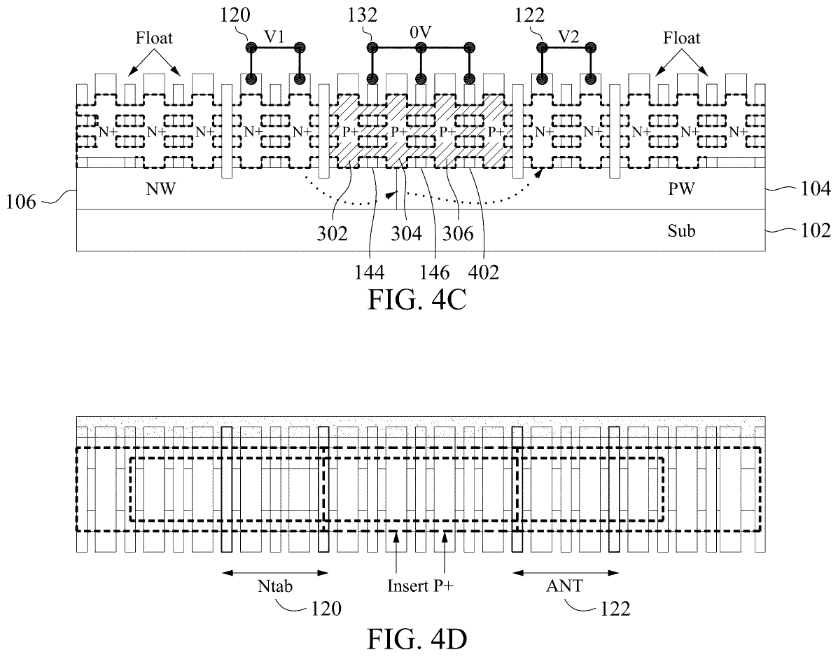

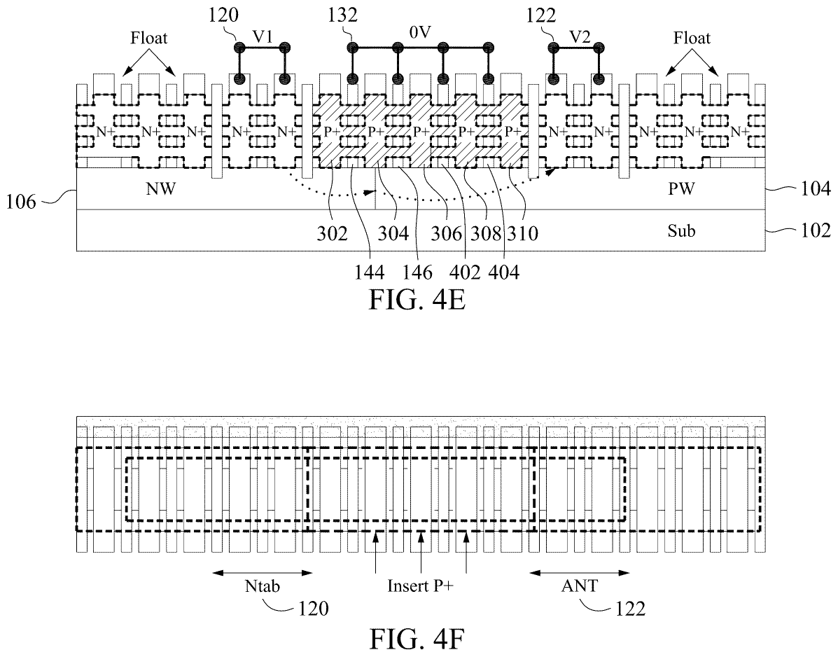

In accordance with example embodiments, the punch through current between NTAB 120 and antenna diode 122 is mitigated or suppressed by forming P+ epi layer structures between them along with biasing any gate structures between NTAB 120 and antenna diode 122 to the ground or 0V. FIGS. 4A and 4B illustrate semiconductor device 100 with P+ epi layer structures and grounded gate structures between NTAB 120 and antenna diode 122. For example, as shown in FIGS. 4A and 4B, a first P+ epi source/drain structure 302, a second P+ epi source/drain structure 304, and a third P+ epi source/drain structure 306 may be formed between NTAB 120 and antenna diode 122. In addition, and as shown in FIGS. 4A and 4B, gate structure 144 and gate structure 146 are biased to the ground (that is, 0V). Biasing gate structure 144 and gate structure 146 to the ground creates a P type behavior in the NW region around the end of gate structure 144 and PW region around the end of gate structure 146 thereby further mitigating any accumulation of charge, and therefore further suppressing the punch through current between NTAB 120 and antenna diode 122. Although, in FIGS. 4A and 4B, semiconductor device 100 is shown to include three P+ epi source/drain structures and two biased gate structures, it can include a different number of P+ epi source/drain structures.

For example, FIGS. 4C and 4D illustrate semiconductor device 100 with four P+ epi layer structures, that is, first P+ epi source/drain structure 302, second P+ epi source/drain structure 304, third P+ epi source/drain structure 306, and fourth P+ epi source/drain structure 308 between NTAB 120 and antenna diode 122. In addition, semiconductor device 100 of FIGS. 4C and 4D includes three grounded gate structures, that is, gate structure 144, gate structure 146, and gate structure 402, between NTAB 120 and antenna diode 122. FIGS. 4E and 4F illustrate semiconductor device 100 with five P+ epi layer structures, that is, first P+ epi source/drain structure 302, second P+ epi source/drain structure 304, third P+ epi source/drain structure 306, fourth P+ epi source/drain structure 308, and fifth P+ epi source/drain structure 310 between NTAB 120 and antenna diode 122. In addition, semiconductor device 100 of FIGS. 4E and 4F includes four grounded gate structures, that is, gate structure 144, gate structure 146, gate structure 402, and gate structure 404 between NTAB 120 and antenna diode 122. Increasing the number of P+ epi source/drain structures and grounded gate structures may enhance suppression or mitigation of the punch through current between NTAB 120 and antenna diode 122, but it increases area penalty.

In examples, semiconductor device 100 may include a combination of different types of punch through mitigation structures discussed above with reference to FIGS. 1A-1J, FIGS. 2A-2L, FIGS. 3A-3F, and FIGS. 4A-4F. For example, semiconductor device 100 may include a combination of any two or more of: a CMG structure, a FBI structure, a P+ epi source/drain structure, and a biased gate structure. That is, semiconductor device 100 may include a CMG structure and a FBI structure, a P+ epi source/drain structure, or a biased gate structure, a FBI structure and a P+ epi source/drain structure or a biased gate structure, etc. In addition, semiconductor device 100 may include a different number of any of a combination of different types of punch through mitigation structures discussed above with reference to FIGS. 1A-1J, FIGS. 2A-2L, FIGS. 3A-3F, and FIGS. 4A-4F. For example, semiconductor device 100 may include a combination of any two or more of: one or more CMG structures, one or more FBI structures, one or more P+ epi source/drain structures, and one or more biased gate structures.

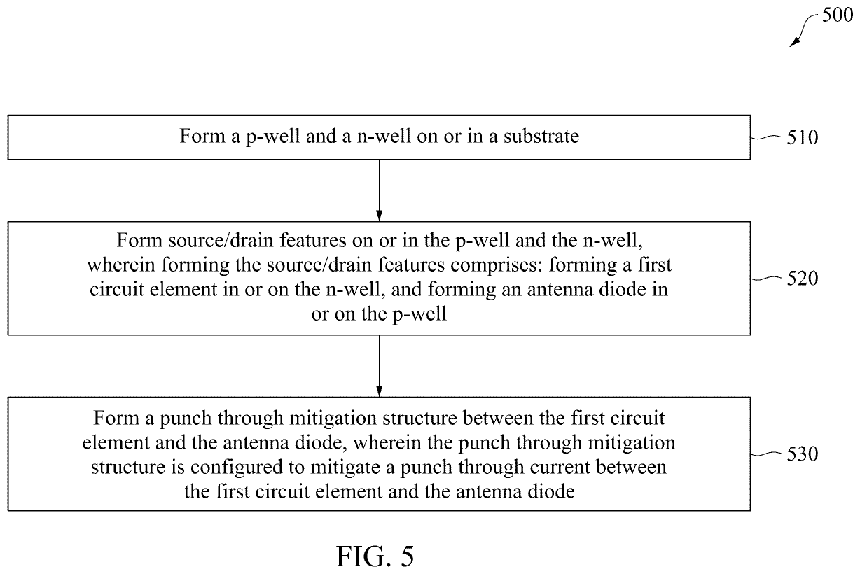

FIG. 5 is a flow diagram illustrating a method 500 for making an integrated circuit, for example, semiconductor device 100 in accordance with some embodiments. Method 500 may be performed by a system including a memory and a processor. In some examples, method 500 may be stored as instructions on a memory device, which when executed by a processor can cause the processor to perform method 500. Ways to implement the stages of method 500 will be described in greater detail below.

At stage 510 of method 500, PW 104 and NW 106 are formed in or on substrate 102. As discussed above PW 102 is doped with P-type dopants, such as boron (for example, BF2), indium, other P-type dopant, or combinations thereof. NW 106 is doped with N-type dopants, such as phosphorus, arsenic, other N-type dopant, or combinations thereof. PW 104 and NW 106 are formed directly on and/or in substrate 102.

At stage 520 of method 500, source/drain features 112 formed on or in NW 106 and PW 104. Forming source/drain features 112 further includes forming a first circuit element (for example, NTAB 120) in or on NW 106, and forming antenna diode 122 in or on PW 104.

At stage 530 of method 500, a punch through mitigation structure formed between the first circuit element and antenna diode 122. The punch through mitigation structure is configured to mitigate a punch through current between the first circuit element and antenna diode 122. For example, and as discussed above, the plurality of punch through mitigation structures can include CMG structures, FBI structures, P+ epi source/drain structures, and a combination thereof.

By executing some or all of the operations of method 500, an semiconductor device 100 layout diagram or an IC layout diagram is generated corresponding to an IC device in which a punch through mitigation structure is formed between a first circuit element and an antenna diode, thereby obtaining semiconductor device 100 as discussed above with respect to FIGS. 1A-1J, FIGS. 2A-2L, FIGS. 3A-3F, and FIGS. 4A-4F.

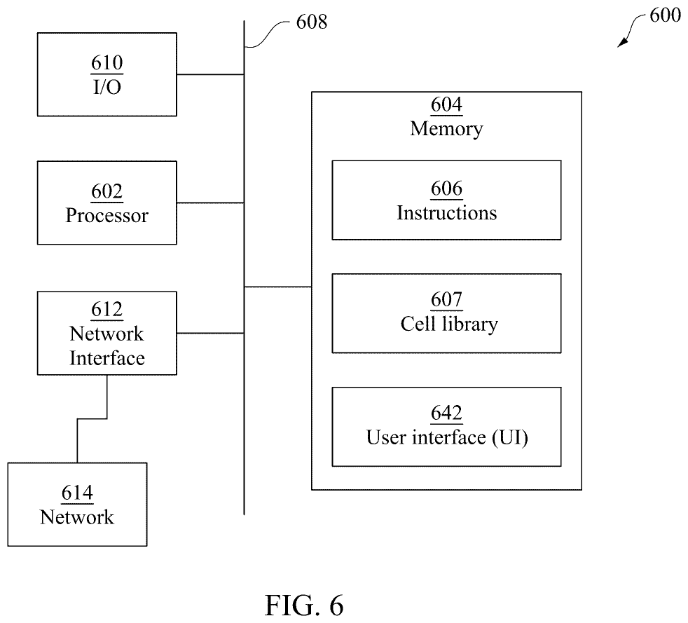

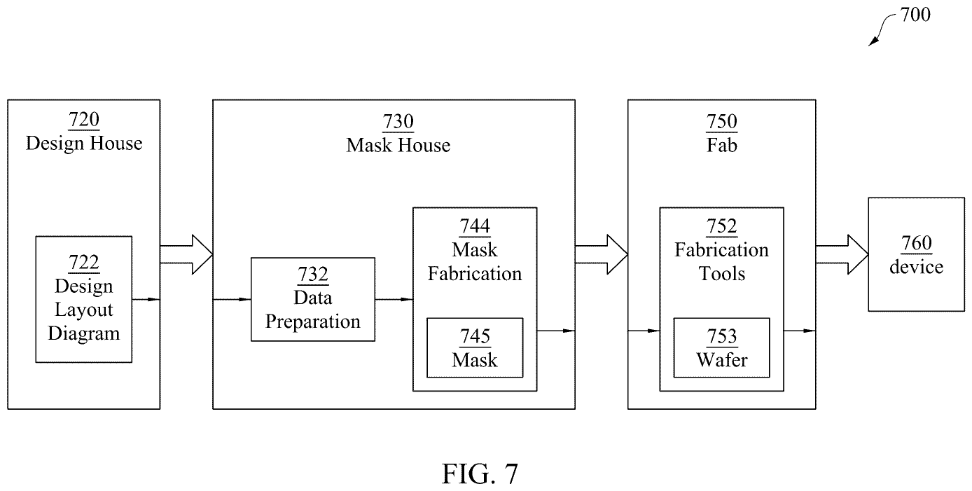

FIG. 6 is a block diagram of a layout diagram generation system 600, in accordance with some embodiments. Methods described herein of forming semiconductor device 100 in accordance with one or more embodiments are implementable, for example, using layout diagram generation system 600. In some embodiments, layout diagram generation system 600 is a general-purpose computing device including a hardware processor 602 and a non-transitory, computer-readable storage medium 604. Storage medium 604, amongst other things, is encoded with, i.e., stores, computer program code 606, i.e., a set of executable instructions. Execution of instructions 606 by hardware processor 602 represents (at least in part) an EDA tool which implements a portion or all of method 500 forming semiconductor device 100 described above with respect to FIG. 5 and/or method 700 of generating an IC layout diagram described with respect to FIG. 7.

Processor 602 is electrically coupled to computer-readable storage medium 604 via a bus 608. Processor 602 is also electrically coupled to an I/O interface 610 by bus 608. A network interface 612 is also electrically connected to processor 602 via bus 608. Network interface 612 is connected to a network 614, so that processor 602 and computer-readable storage medium 604 are capable of connecting to external elements via network 604. Processor 602 is configured to execute computer program code 606 encoded in computer-readable storage medium 604 in order to cause layout diagram generation system 600 to be usable for performing a portion or all of the noted processes and/or methods. In one or more embodiments, processor 602 is a central processing unit (CPU), a multi-processor, a distributed processing system, an application specific integrated circuit (ASIC), and/or a suitable processing unit.

In one or more embodiments, computer-readable storage medium 604 is an electronic, magnetic, optical, electromagnetic, infrared, and/or a semiconductor system (or apparatus or device). For example, computer-readable storage medium 604 includes a semiconductor or solid-state memory, a magnetic tape, a removable computer diskette, a random access memory (RAM), a read-only memory (ROM), a rigid magnetic disk, and/or an optical disk. In one or more embodiments using optical disks, computer-readable storage medium 604 includes a compact disk-read only memory (CD-ROM), a compact disk-read/write (CD-R/W), and/or a digital video disc (DVD).

In one or more embodiments, computer-readable storage medium 604 stores computer program code 606 configured to cause layout diagram generation system 600 (where such execution represents (at least in part) the EDA tool) to be usable for performing a portion or all of the noted processes and/or methods. In one or more embodiments, computer-readable storage medium 604 also stores information which facilitates performing a portion or all of the noted processes and/or methods. In one or more embodiments, computer-readable storage medium 604 stores cell library 607 of cells including such cells as disclosed herein with respect to FIGS. FIGS. 1A-1J, FIGS. 2A-2L, FIGS. 3A-3F, and FIGS. 4A-4F.

Layout diagram generation system 600 includes I/O interface 610. I/O interface 610 is coupled to external circuitry. I/O interface 610 may include a keyboard, keypad, mouse, trackball, trackpad, touchscreen, and/or cursor direction keys for communicating information and commands to processor 602.

Layout diagram generation system 600 also includes network interface 612 coupled to processor 602. Network interface 612 allows layout generation system 600 to communicate with network 614, to which one or more other computer systems are connected. Network interface 612 may include wireless network interfaces or wired network interfaces.

Layout diagram generation system 600 is configured to receive information through I/O interface 610. The information received through I/O interface 610 includes one or more of instructions, data, design rules, libraries of standard cells, and/or other parameters for processing by processor 602. The information is transferred to processor 602 via bus 608. Layout diagram generation system 600 is configured to receive information related to a UI through I/O interface 610. The information is stored in computer-readable medium 604 as user interface (UI) 642.

FIG. 7 is a block diagram of a device manufacturing system 700, and a device manufacturing flow associated therewith, in accordance with some embodiments. In some embodiments, based on a device layout diagram, at least one of (A) one or more semiconductor masks or (B) at least one component in a layer of a semiconductor integrated circuit is fabricated using manufacturing system 700.

In FIG. 7, device manufacturing system 700 includes entities, such as a design house 720, a mask house 730, and a manufacturer/fabricator (“fab”) 750, that interact with one another in the design, development, and manufacturing cycles and/or services related to manufacturing a device 760. The entities in system 700 are connected by a communications network. In some embodiments, the communications network is a single network. In some embodiments, the communications network is a variety of different networks, such as an intranet and the Internet. The communications network includes wired and/or wireless communication channels. Each entity interacts with one or more of the other entities and provides services to and/or receives services from one or more of the other entities.

Design house (or design team) 720 generates an IC design layout diagram 722. IC design layout diagram 722 includes various geometrical patterns, semiconductor device 100 discussed above with respect to FIGS. FIGS. 1A-1J, FIGS. 2A-2L, FIGS. 3A-3F, and FIGS. 4A-4F. The geometrical patterns correspond to patterns of metal, oxide, or semiconductor layers that make up the various components of device 760 to be fabricated. The various layers combine to form various IC features. For example, a portion of IC design layout diagram 722 includes various IC features, such as an active region, gate electrode, source and drain, metal lines or vias of an interlayer interconnection, and openings for bonding pads, to be formed in a semiconductor substrate (such as a silicon wafer) and various material layers disposed on the semiconductor substrate. Design house 720 implements a proper design procedure to form design layout diagram 722. The design procedure includes one or more of logic design, physical design or place and route. IC design layout diagram 722 is presented in one or more data files having information of the geometrical patterns. For example, IC design layout diagram 722 can be expressed in a GDSII file format or DFII file format.

Mask house 730 includes data preparation 732 and mask fabrication 744. Mask house 730 uses design layout diagram 722 to manufacture one or more masks 745 to be used for fabricating the various layers of device 760 according to design layout diagram 722. Mask house 730 performs mask data preparation 732, where design layout diagram 722 is translated into a representative data file (RDF). Mask data preparation 732 provides the RDF to mask fabrication 744. Mask fabrication 744 includes a mask writer. A mask writer converts the RDF to an image on a substrate, such as a mask (reticle) 745 or a semiconductor wafer 753. The design layout diagram 722 is manipulated by mask data preparation 732 to comply with particular characteristics of the mask writer and/or requirements of IC fab 750. In FIG. 7, mask data preparation 732 and mask fabrication 744 are illustrated as separate elements. In some embodiments, mask data preparation 732 and mask fabrication 744 can be collectively referred to as mask data preparation.

Mask data preparation 732 may include optical proximity correction (OPC) which uses lithography enhancement techniques to compensate for image errors, such as those that can arise from diffraction, interference, other process effects and the like. OPC adjusts design layout diagram 722. Mask data preparation 732 includes further resolution enhancement techniques (RET), such as off-axis illumination, sub-resolution assist features, phase-shifting masks, other suitable techniques, and the like or combinations thereof. In some embodiments, inverse lithography technology (ILT) is also used, which treats OPC as an inverse imaging problem.

Mask data preparation 732 may include a mask rule checker (MRC) that checks the design layout diagram 722 that has undergone processes in OPC with a set of mask creation rules which contain certain geometric and/or connectivity restrictions to ensure sufficient margins, to account for variability in semiconductor manufacturing processes, and the like. The MRC may modify the IC design layout diagram 722 to compensate for limitations during mask fabrication 744, which may undo part of the modifications performed by OPC in order to meet mask creation rules.

Mask data preparation 732 may include lithography process checking (LPC) that simulates processing that will be implemented by fab 750 to fabricate device 760. LPC simulates this processing based on design layout diagram 722 to create a simulated manufactured device, such as device 760. The processing parameters in LPC simulation can include parameters associated with various processes of the manufacturing cycle, parameters associated with tools used for manufacturing the device, and/or other aspects of the manufacturing process. LPC takes into account various factors, such as aerial image contrast, depth of focus (“DOF”), mask error enhancement factor (“MEEF”), other suitable factors, and the like or combinations thereof. In some embodiments, after a simulated manufactured device has been created by LPC, if the simulated device is not close enough in shape to satisfy design rules, OPC and/or MRC are be repeated to further refine design layout diagram 722.

It should be understood that the above description of mask data preparation 732 has been simplified for the purposes of clarity. Data preparation 732 may include additional features such as a logic operation (LOP) to modify the IC design layout diagram 722 according to manufacturing rules. Additionally, the processes applied to design layout diagram 722 during data preparation 732 may be executed in a variety of different orders.

After mask data preparation 732 and during mask fabrication 744, a mask 745 or a group of masks 745 are fabricated based on the modified design layout diagram 722. Mask fabrication 744 includes performing one or more lithographic exposures based on design layout diagram 722. An electron-beam (e-beam) or a mechanism of multiple e-beams is used to form a pattern on a mask (photomask or reticle) 745 based on the modified design layout diagram 722. Mask 745 can be formed in various technologies. In some examples, mask 745 is formed using binary technology. In some embodiments, a mask pattern includes opaque regions and transparent regions. A radiation beam, such as an ultraviolet (UV) or EUV beam, used to expose the image sensitive material layer (e.g., photoresist) which has been coated on a wafer, is blocked by the opaque region and transmits through the transparent regions. In one example, a binary mask version of mask 745 includes a transparent substrate (e.g., fused quartz) and an opaque material (e.g., chromium) coated in the opaque regions of the binary mask. In another example, mask 745 is formed using a phase shift technology. In a phase shift mask (PSM) version of mask 745, various features in the pattern formed on the phase shift mask are configured to have proper phase difference to enhance the resolution and imaging quality. In various examples, the phase shift mask can be attenuated PSM or alternating PSM. The mask(s) generated by mask fabrication 744 is used in a variety of processes. For example, such a mask(s) is used in an ion implantation process to form various doped regions in semiconductor wafer 753, in an etching process to form various etching regions in semiconductor wafer 753, and/or in other suitable processes.

Fab 750 is an IC fabrication business that includes one or more manufacturing facilities for the fabrication of a variety of different IC products. In some examples, fab 750 is a semiconductor foundry. For example, there may be a manufacturing facility for the front end fabrication of a plurality of IC products (front-end-of-line (FEOL) fabrication), while a second manufacturing facility may provide the back end fabrication for the interconnection and packaging of the IC products (back-end-of-line (BEOL) fabrication), and a third manufacturing facility may provide other services for the foundry business.

Fab 750 includes wafer fabrication tools 752 configured to execute various manufacturing operations on semiconductor wafer 753 such that device 760 is fabricated in accordance with the mask(s), e.g., mask 745. Fabrication tools 752 may include one or more of a wafer stepper, an ion implanter, a photoresist coater, a process chamber, e.g., a CVD chamber or LPCVD furnace, a CMP system, a plasma etch system, a wafer cleaning system, or other manufacturing equipment capable of performing one or more suitable manufacturing processes as discussed herein.

Fab 750 uses mask(s) 745 fabricated by mask house 730 to fabricate device 760. Thus, fab 750 at least indirectly uses design layout diagram 722 to fabricate device 760. In some examples, semiconductor wafer 753 is fabricated by fab 750 using mask(s) 745 to form device 760. In some embodiments, the IC fabrication includes performing one or more lithographic exposures based at least indirectly on design layout diagram 722. Semiconductor wafer 753 includes a silicon substrate or other proper substrate having material layers formed thereon. Semiconductor wafer 753 further includes one or more of various doped regions, dielectric features, multilevel interconnects, and the like (formed at subsequent manufacturing steps).

In accordance with disclosed embodiments, a semiconductor device comprises: a semiconductor substrate; a n-well in or on the substrate; a p-well in or on the substrate; a first circuit element formed in or on the n-well; an antenna diode formed in or on the p-well; and a punch through mitigation structure formed between the first circuit element and the antenna diode, wherein the punch through mitigation structure comprises a first cut metal gate structure formed between the first circuit element and the antenna diode, and wherein the first cut metal gate structure comprises a Source/Drain (S/D) structure with dopants replaced with an insulating material.

In accordance with further disclosed embodiments, a semiconductor device comprises: a semiconductor substrate; a n-well in or on the substrate; a p-well in or on the substrate; a first circuit element formed in or on the n-well; an antenna diode formed in or on the p-well; and a cut metal gate structure formed between the first circuit element and the antenna diode, wherein the cut metal gate structure comprises a Source/Drain (S/D) structure with dopants replaced with an insulating material.

In accordance with still further disclosed embodiments, a method of making an integrated circuit comprises: forming a p-well and a n-well on or in a substrate; forming gate features on or in the p-well and the n-well; forming source/drain features on or in the n-well and the p-well, wherein forming the source/drain features comprises: forming a first circuit element in or on the n-well, and forming an antenna diode in or on the p-well; and forming a punch through mitigation structure between the first circuit element and the antenna diode, wherein the punch through mitigation structure comprises a first cut metal gate structure formed between the first circuit element and the antenna diode, and, wherein the first cut metal gate structure comprises a Source/Drain (S/D) structure with dopants replaced with an insulating material.

This disclosure outlines various embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device comprising:
a semiconductor substrate;
a n-well in or on the substrate;
a p-well in or on the substrate;
a first circuit element formed in or on the n-well;
an antenna diode formed in or on the p-well; and
a punch through mitigation structure formed between the first circuit element and the antenna diode, wherein the punch through mitigation structure comprises a first cut metal gate structure formed between the first circuit element and the antenna diode, and wherein the first cut metal gate structure comprises a Source/Drain (S/D) structure with dopants replaced with an insulating material.

2. The semiconductor device of claim 1, wherein the punch through mitigation structure further comprises at least two cut metal gate structures formed between the first circuit element and the antenna diode.

3. The semiconductor device of claim 1, wherein the punch through mitigation structure further comprises a fully bulk isolation structure formed between the first circuit element and the antenna diode.

4. The semiconductor device of claim 1, wherein the punch through mitigation structure further comprises a P+ epitaxial layer structure formed between the first circuit element and the antenna diode.

5. The semiconductor device of claim 1, wherein the punch through mitigation structure further comprises a grounded gate structure formed between the first circuit element and the antenna diode.

6. The semiconductor device of claim 1, wherein the punch through mitigation structure further comprises one of the following: one or more cut metal gate structure, one or more fully bulk isolation structure, one or more P+ epitaxial layer structure, and one or more grounded gate structure formed between the first circuit element and the antenna diode.

7. The semiconductor device of claim 1, wherein the punch through mitigation structure further comprises a second cut metal gate structure formed between the first circuit element and the antenna diode, wherein the second cut metal gate structure is bigger than the first cut metal gate structure.

8. The semiconductor device of claim 1, wherein the punch through mitigation structure further comprises a first fully bulk isolation structure and a second fully bulk isolation structure formed between the first circuit element and the antenna diode, wherein the second fully bulk isolation structure is bigger than the first fully bulk isolation structure.

9. A semiconductor device comprising:
a semiconductor substrate;
a p-type doped region formed in or on the substrate;
a n-type doped region formed in or on the substrate;
a first circuit element formed in or on the n-type doped region;
an antenna diode formed in or on the p-type doped region; and
a first cut metal gate structure formed between the first circuit element and the antenna diode, wherein the first cut metal gate structure comprises a Source/Drain (S/D) structure with dopants replaced with an insulating material.

10. The semiconductor device of claim 9, further comprising at least one another cut metal gate structure formed between the first circuit element and the antenna diode.

11. The semiconductor device of claim 9, further comprising a second cut metal gate structure formed between the first circuit element and the antenna diode, wherein the second cut metal gate structure is bigger than the first cut metal gate structure.

12. The semiconductor device of claim 9, further comprising a fully bulk isolation structure cut formed between the first circuit element and the antenna diode.

13. The semiconductor device of claim 9, further comprising a P+epitaxial layer structure formed between the first circuit element and the antenna diode.

14. The semiconductor device of claim 9, further comprising a grounded gate structure formed between the first circuit element and the antenna diode.

15. The semiconductor device of claim 9, wherein the first cut metal gate structure formed on a source/drain structure between the first circuit element and the antenna diode.

16. The semiconductor device of claim 9, wherein the first circuit element comprises N-well taps and biasing cell.

17. A method of making a semiconductor device, comprising:
forming a p-well and a n-well on or in a substrate;
forming gate features on or in the p-well and the n-well;
forming source/drain features on or in the p-well and the n-well, wherein forming the source/drain features comprises:
forming a first circuit element in or on the n-well, and
forming an antenna diode in or on the p-well; and
forming a punch through mitigation structure between the first circuit element and the antenna diode, wherein the punch through mitigation structure comprises a first cut metal gate structure formed between the first circuit element and the antenna diode, and wherein the first cut metal gate structure comprises a Source/Drain (S/D) structure with dopants replaced with an insulating material.

18. The method of claim 17, wherein forming the punch through mitigation structure further comprises forming a second cut metal gate structure.

19. The method of claim 17, wherein forming the punch through mitigation structure further comprises forming a fully bulk isolation gate structure.

20. The method of claim 17, wherein forming the punch through mitigation structure further comprises forming a P+ epitaxial layer structure.
